(19) United States
(12) Patent Application Publication
(10) Pub. No.: US 2025/0226324 A1
(43) Pub. Date: Jul. 10, 2025

(54) DIE-TO-DIE PROBE PAD CONNECTION IN A STACKED SEMICONDUCTOR DEVICE

(71) Applicant: Micron Technology, Inc., Boise, ID (US)

(72) Inventors: Bharat Bhushan, Boise, ID (US); Kunal R. Parekh, Boise, ID (US); Bret K. Street, Meridian, ID (US); Akshay N. Singh, Boise, ID (US)

(21) Appl. No.: 19/011,357

(22) Filed: Jan. 6, 2025

Related U.S. Application Data
(60) Provisional application No. 63/619,151, filed on Jan. 9, 2024.

(51) Int. Cl. H01L 23/538; H01L 21/768; H01L 25/07; H10B 80/00

(52) U.S. Cl. CPC H01L 23/5384; H01L 21/76807; H01L 23/5386; H01L 25/074; H10B 80/00; H01L 2225/06541

(57) ABSTRACT

Methods, systems, and devices for die-to-die probe pad connection in a stacked semiconductor device are described. The stacked semiconductor device may include a first probe pad that is on a physically accessible surface of a stack of semiconductor dies. The stacked semiconductor device may include a second probe pad located at a physically inaccessible surface of (e.g., within) the stack of semiconductor dies. And the stacked semiconductor device may include a conductive path that electrically couples the first probe pad with the second probe pad.

### CROSS REFERENCE

The present Application for Patent claims the benefit of U.S. Provisional Patent Application No. 63/619,151 by BHUSHAN et al., entitled “DIE-TO-DIE PROBE PAD CONNECTION IN A STACKED SEMICONDUCTOR DEVICE,” filed Jan. 9, 2024, assigned to the assignee hereof, and expressly incorporated by reference in its entirety herein.

### TECHNICAL FIELD

The following relates to one or more systems for memory, including die-to-die probe pad connection in a stacked semiconductor device.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

In some examples, a memory device may include multiple dies stacked on each other. Techniques for probing stacked dies may be desired.

### BRIEF DESCRIPTION OF THE DRAWINGS

FIG. 1 shows an example of a system that supports die-to-die probe pad connection in a stacked semiconductor device in accordance with examples as disclosed herein.

FIG. 2 shows an example of an architecture that supports die-to-die probe pad connection in a stacked semiconductor device in accordance with examples as disclosed herein.

FIGS. 3A and 3B show examples of a die that supports die-to-die probe pad connection in a stacked semiconductor device in accordance with examples as disclosed herein.

FIG. 4 shows an example of a stacked semiconductor device that supports die-to-die probe pad connection in accordance with examples as disclosed herein.

FIG. 5 shows an example of a process flow and a stacked semi-conductor device in accordance with examples as disclosed herein.

FIG. 6 shows a flowchart illustrating a method or methods that support die-to-die probe pad connection in a stacked semiconductor device in accordance with examples as disclosed herein.

### DETAILED DESCRIPTION

A semiconductor conductor device may include one or more stacked dies. For example, a memory system may include one or more memory dies stacked (e.g., above one another) with one or more logic dies in the same package. The stacked dies may be electrically coupled by silicon-through-vias (TSVs) and may be bonded together (e.g., physically coupled) using one or more bonding techniques. In some examples, data stored in a die of the stacked dies may become corrupted during bonding (e.g., due to high temperatures used during bonding, due to electrostatic discharge (ESD) during bonding) and, if uncorrected, may impair the functionality and performance of the memory system. Although a die may include a probe pad for probing the die to correct data errors, using other different techniques the probe pad may be physically inaccessible (e.g., by a probing device) after bonding, which may prevent probing the probe pad and prevent correcting the data errors.

According to the present disclosure, a stacked semiconductor device (e.g., a stacked memory system) may be manufactured with a conductive path that electrically couples a probe pad (which may be physically accessible after bonding) of a first die with a probe pad of a second die so that, after bonding, data in the second die can be probed (e.g., read and potentially re-written to correct for any errors during bonding) even though the probe pad of the second die is physically inaccessible (e.g., is covered by one or more materials or dies). Among other benefits, enabling post-bonding probing of a die may allow a manufacturer or a customer to realize the advantages of advanced high temperature-bonding techniques without the cost of data corruption, because corrupted data in the dies (e.g., due to high-temperature bonding, due to bonding-ESD) can be detected and re-written using the physically accessible probe pad unlike other different techniques.

In addition to applicability in memory systems as described herein, techniques for connecting the probe pads of a stacked semiconductor device may be generally implemented to improve the performance of various electronic devices and systems (e.g., including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling post-bonding probing (and thus the use of advance manufacturing techniques), which in turn may improve user experience, among other benefits.

Features of the disclosure are illustrated and described in the context of systems and architectures. Features of the disclosure are further illustrated and described in the context of dies, process flows, and flowcharts.

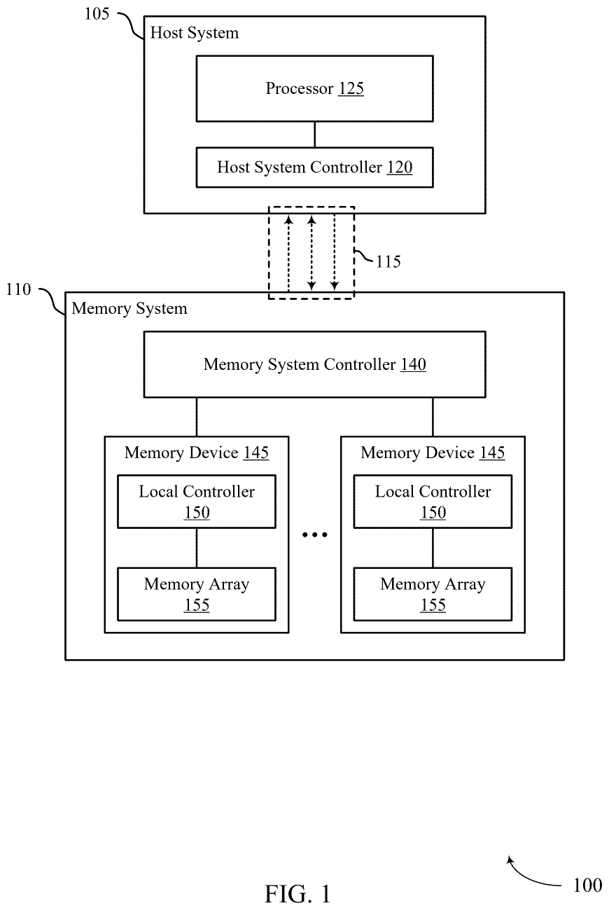

FIG. 1 illustrates an example of a system 100 that supports die-to-die probe pad connection in a stacked semiconductor device in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, the system 100 may be a stacked memory system (e.g., a high bandwidth memory (HBM) system) in that one or more memory dies (e.g., the memory devices 145) of the memory system are stacked on each other and bonded to one or more logic dies (e.g., the host system 105). Bonding two components (e.g., dies, bond pads) refers to physically coupling the two components and in some examples may establish electrical connections between the two components (or between sub-components of the two components, such as die-interface bond pads).

The dies in a stacked system (e.g., a stacked memory system) may be bonded using one or more bonding techniques such as wafer-to-wafer (W2W) hybrid bonding, stack-to-wafer (S2W) hybrid bonding, (also referred to as die-to-wafer hybrid bonding or chip-to-wafer (C2W) hybrid bonding), and die-to-die (D2D) hybrid bonding (also referred to as chip-to-chip hybrid bonding). Use of high temperatures (e.g.,>300° C.) for the bonding technique(s) may be associated with various advantages, but may cause data corruption that, if uncorrected, impairs the functionality and performance of the dies in the stacked system. For example, in a memory die, fuse data (e.g., used for operating the memory die) may be corrupted during W2W bonding, during S2W bonding, or during both. ESD and other phenomenon during manufacturing may also corrupt pre-existing data (e.g., data that exists before bonding) in the stacked system.

A die may have a probe pad that is used (e.g., during manufacturing) to probe a memory of the die before the die is bonded to another die for the stacked system, where probing a component refers to reading data from the component and may include correcting corrupted data. For example, the probe pad may be electrically coupled with access circuitry for one or more memory arrays of the die so that data stored in the memory arrays can be accessed by the probe pad. Although physically accessible (e.g., capable of being physically contacted by a probing device, on a physically accessible surface of the die) in the early stages of manufacturing, the probe pad of a die may be physically covered by another die after the memory die is bonded with that die (e.g., another memory die, a logic die). Thus, the die may be physically inaccessible for probing after bonding, which may prevent a manufacturer from detecting and correcting bonding-caused errors that impair performance of the stacked system.

The present disclosure provides for a stacked system (and a method of manufacturing the stacked system) that includes a conductive interconnect structure that electrically couples the internal probe pad of a first die with an external (e.g., probe-contactable, air-exposed, accessible through a bump connector) probe pad of a second die so that post-bonding probing can be performed on the second die. The conductive interconnect structure may include a conductive interconnect (e.g., a RDL interconnect) that may also be referred to as an electrical interconnect, a conductive trace, or a conductive layer, among other suitable terminology. In some example, post-bonding probing may be referred to as re-probing (e.g., if the die being post-bonding probed has already been probed during an earlier stage of manufacturing).

A memory system may also be referred to as a semiconductor device or other suitable terminology. Although described with reference to examples that feature a particular quantity of memory dies and logic dies, the techniques and designs described may be extended to any quantity of memory dies and logic dies, and any ratio of memory dies to logic dies. Although described with reference to a memory system, the techniques described herein may be implemented in other types of systems that include stacked dies. In some examples, a die may also be referred to as a chip or other suitable terminology.

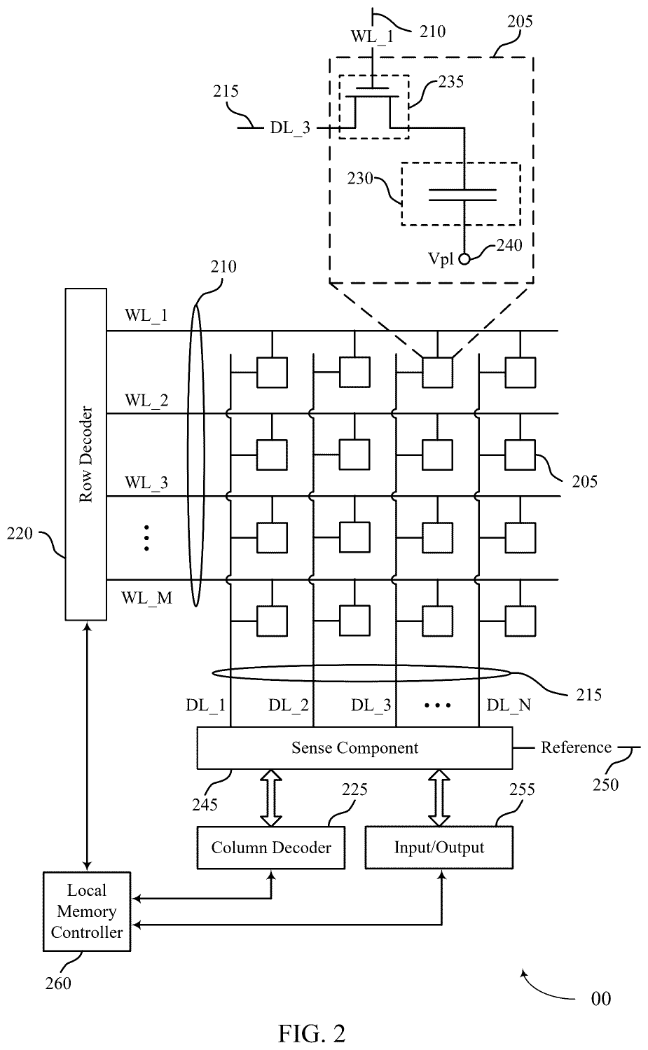

FIG. 2 illustrates an example of an architecture 200 (e.g., a memory architecture) that supports die-to-die probe pad connection in a stacked semiconductor device in accordance with examples as disclosed herein. The architecture 200 may be implemented in a memory system 110 or one or more components thereof (e.g., memory device 145). Aspects of the architecture 200 may be referred to as or implemented in a semiconductor component, such as a memory die.

The architecture 200 includes memory cells 205 that are programmable to store information. In some examples, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). Memory cells 205 may be arranged in an array, such as in a memory array 155.

In the example of architecture 200, a memory cell 205 may include a storage component, such as capacitor 230, and a selection component 235 (e.g., a cell selection component, a transistor). A capacitor 230 may be a dielectric capacitor or a ferroelectric capacitor. A node of the capacitor 230 may be coupled with a voltage source 240, which may be a cell plate reference voltage, such as Vpl, or may be a ground voltage, such as Vss. A charge stored by a memory cell 205 (e.g., by a capacitor 230) may be representative of a programmed state. Other memory architectures that support the techniques described herein may implement different types or arrangements of storage components and associated circuitry (e.g., with or without a selection component).

The architecture 200 may include various arrangements of access lines, such as word lines 210 and digit lines 215. An access line may be a conductive line that is coupled with a memory cell 205, and may be used to perform access operations on the memory cell 205. Word lines 210 may be referred to as row lines, and digit lines 215 may be referred to as column lines or bit lines, among other nomenclature. Memory cells 205 may be positioned at intersections of access lines, and an intersection may be referred to as an address of a memory cell 205.

In some architectures, a word line 210 may be coupled with a gate of a selection component 235 of a memory cell 205, and may be operable to control (e.g., switch, modulate a conductivity of) the selection component 235. A digit line 215 may be operable to couple a memory cell 205 with a sense component 245. In some architectures, a memory cell 205 (e.g., a capacitor 230) may be coupled with a digit line 215 during portions of an access operation. For example, a word line 210 and a selection component 235 of a memory cell 205 may be operable to couple or isolate a capacitor 230 of the memory cell 205 with a digit line 215.

Operations such as reading and writing may be performed on memory cells 205 by activating (e.g., applying a voltage to) access lines such as a word line 210 or a digit line 215. Accessing the memory cells 205 may be controlled through a row decoder 220, or a column decoder 225, or a combination thereof. For example, a row decoder 220 may receive a row address (e.g., from a local memory controller 260) and activate a word line 210 based on a received row address, and a column decoder 225 may receive a column address and activate a digit line 215 based on a received column address. Selecting or deselecting a memory cell 205 may include activating or deactivating a selection component 235 using a word line 210. For example, a capacitor 230 may be isolated from a digit line 215 when the selection component 235 is deactivated, and the capacitor 230 may be coupled with the digit line 215 when the selection component 235 is activated.

A sense component 245 may be operable to detect a state (e.g., a charge) stored by a capacitor 230 of a memory cell 205 and determine a logic state of the memory cell 205 based on the stored state. A sense component 245 may include one or more sense amplifiers to amplify or otherwise convert a signal resulting from accessing the memory cell 205. The sense component 245 may compare a signal detected from the memory cell 205 with a reference 250 (e.g., a reference voltage). The detected logic state of the memory cell 205 may be provided as an output of the sense component 245 (e.g., via an input/output 255), and may indicate the detected logic state to another component of a memory system 110 that implements the architecture 200.

The local memory controller 260 may control the accessing of memory cells 205 through the various components (e.g., a row decoder 220, a column decoder 225, a sense component 245), and may be an example of or otherwise included in a local controller 150, or a memory system controller 140, or both. In some examples, one or more of a row decoder 220, a column decoder 225, and a sense component 245 may be co-located with or included in the local memory controller 260. The local memory controller 260 may be operable to receive commands or data from one or more different controllers (e.g., a host system controller 120, a memory system controller 140), translate the commands or the data into information that can be used by the architecture 200, initiate or control one or more operations of the architecture 200, and communicate data from the architecture 200 to a host (e.g., a host system 105) based on performing the one or more operations.

The local memory controller 260 may be operable to perform one or more access operations on one or more memory cells 205 of the architecture 200. Examples of an access operation may include a write operation, a read operation, a refresh operation, a precharge operation, or an activate operation, among others. In some examples, an access operation may be performed by or otherwise coordinated by the local memory controller 260 in response to one or more access commands (e.g., from a host system 105). The local memory controller 260 may be operable to perform other access operations not listed here or other operations related to the operating of the architecture 200 that are not directly related to accessing the memory cells 205.

In some examples, the architecture 200 may be an example of an architecture of a stacked memory system where one or more memory dies (which may include the memory cells 205 and supporting access circuitry) are stacked with one or more logic dies. A logic die may refer to a die that performs processing functions for another device, such as a host device, and a memory die may refer to a die that stores data for a logic die or a host device. The term access circuitry may refer to the circuitry (e.g., decoders, controllers, sense components) that facilitates accessing (e.g., writing and reading) the memory cells 205.

Data may be written to a die before a bonding process is used to bond a die with another die. For example, the memory cells 205 of a memory die may store data (e.g., fuse data, register data) for operating the memory die. To enable the post-bonding probing of a die (e.g., to correct errors introduced in the data by the bonding process), a die may be manufactured with a conductive interconnect structure that electrically couples the probe pad of the die with A) a TSV that at least partially extends through the die (and which may be electrically coupled with a TSV of another die before or after the bonding process) and B) a die-interface bond pad of the die (which may be electrically coupled with TSV of another die, such as a logic die, after the bonding process). The conductive interconnect structure may include a conductive interconnect (e.g., RDL interconnect) and one or more vias.

The other dies of the stacked system may also be manufactured with similar conductive interconnect structures that, collectively (after manufacturing), form a conductive path between the external (e.g., physically accessible) probe pad of the stacked system and the internal (e.g., physically inaccessible) probe pad(s) of the stacked system. The conductive path may enable probing of the dies at one or more stages of the manufacturing process or after the manufacturing process.

The term “electrically coupled with” may refer to the relationship between components in which electrical signals are capable of being passed between the components, either directly (e.g., component-to-component) or indirectly (e.g., through one or more intermediary or intervening components). The term “physically coupled with” may refer to a relationship between components in which the components are in contact with each other.

The term “conductive path” may refer to a path that is capable of conveying electrical signals from one end of the path to the other end of the path. So, a conductive path between a first component and a second component may be a path that is capable of conveying electrical signals between the first component and the second component. A conductive path may include one or more materials or components that are electrically coupled. In some examples a conductive path may be referred to as an electrical path or other suitable terminology.

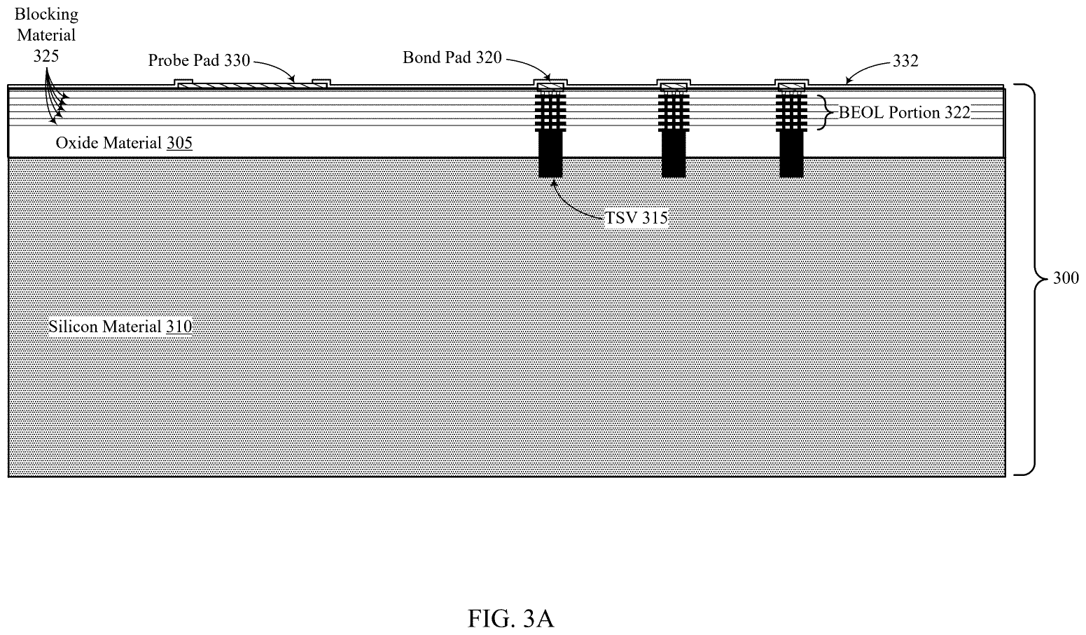

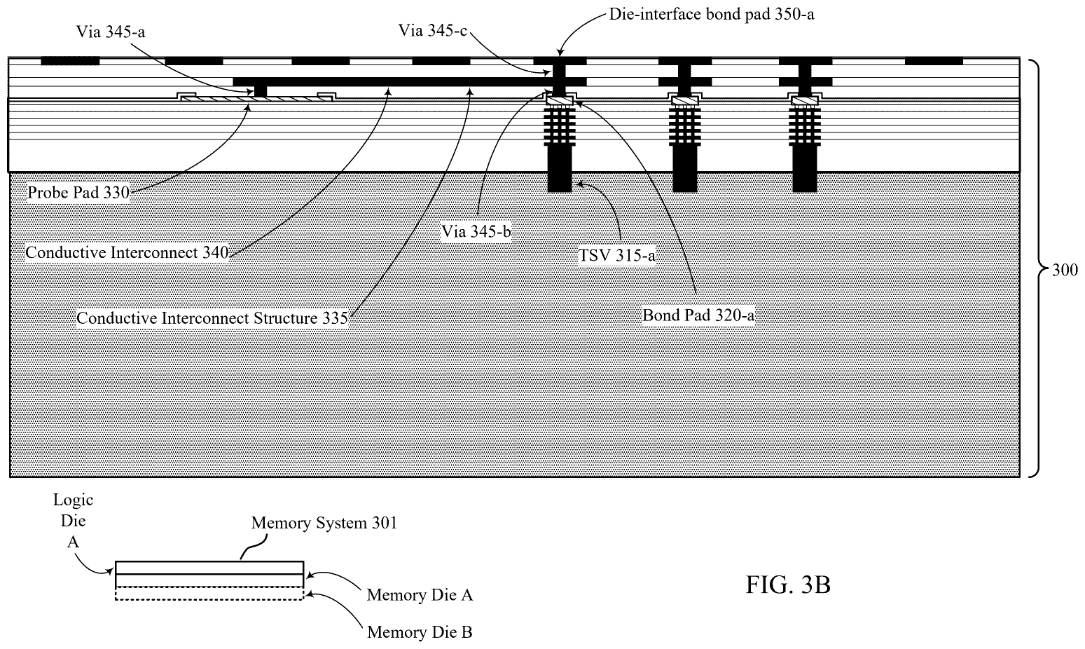

FIG. 3A shows an example of a die 300 after a first one or more stages in manufacturing in accordance with examples as disclosed herein. The die 300 may include silicon material 310 and an oxide material 305 and that is stacked on the silicon material 310. Memory cells of the die 300 (not shown) may be wholly or partially formed within the oxide material 305, within the silicon material 310, or within both. The die 300 may be an example of a memory die or a logic die.

The die 300 may include TSVs 315, which may be embedded within the die 300 and which may extend at least partially through the oxide material 305, the silicon material 310, or both. The TSVs 315 may be formed using the via-first or via-middle process. In some examples, the TSVs 315 may be formed using the via-last process. In some examples, the TSVs 315 may include or be coupled with a back-end-of-line (BEOL) portion 322. A BEOL portion 322 may refer to various interconnects that are formed within the oxide material 305.

A TSV 315 may include a bond pad 320 (e.g., a conductive electrical contact), each of which may be made up of or may include a conductive material. For example, a TSV 315 (and potentially the BEOL portion 322) may be copper and the bond pad 320 of the TSV 315 may be aluminum (Al). In some examples, the die 300 may include a blocking material 325 deposited on top of layers (e.g., copper layers) of the BEOL portion 322 to prevent diffusion into the oxide material 305. In some examples, the portions of the oxide material 305 separated by the layer of the blocking material 325 may be referred to as oxide layers or other suitable terminology.

The die 300 may include a probe pad 330, which may be a conductive electrical contact for probing the memory cells of the memory die. In some examples, the probe pad 330 may be made up of or may include an aluminum material. The probe pad 330 may be electrically coupled with access circuitry for a memory of the memory die and may be configured to convey electrical signals to and/or from the access circuitry (e.g., for probing the memory). In some examples, the probe pad 330 may be used for an initial probing of the die 300 that occurs before bonding of the die 300 with another die.

A silicon nitride (SiN) material 332 may be deposited over (e.g., on) the oxide material 305, the bond pads 320, and at least a portion of the probe pad 330. In some examples, the silicon nitride material 332 may be a thin pass SiN layer (e.g., less than .5 μm). The silicon nitride material 332 may not be present in other techniques and may prevent moisture absorption and mitigate corrosion of conductive (e.g., aluminum) interconnects.

Although initially exposed at a surface of the die 300 for probing, the probe pad 330 may become physically inaccessible (e.g., incapable of being physically contacted by a probing device) later in the manufacturing process (e.g., after the die 300 is bonded with another memory die). Put another way, after a bonding process with another die, the probe pad 330 may be located at or disposed on a physically inaccessible surface of the die 300 (or the stacked semiconductor device that includes the die 300). At another stage of manufacturing, described with reference to FIG. 3B, a conductive interconnect structure may be added to the die 300 so that a subsequent bonding process with another die electrically couples the probe pad 330 with a probe pad of the other die. This way, the probe pad 330 may be electrically accessible (e.g., capable of receiving electrical signals from a probing device) even though the probe pad is not physically accessible.

The described technique may result in a distinct quantity of probe marks per die. For example, post-fabrication the top memory die may have one probe mark, the logic-adjacent memory die may have two probe marks (e.g., rather than having one probe mark as in other techniques), and the logic may have four probe marks (e.g., rather than having three probe marks as in other techniques). Thus, probe marks may be used to reverse engineer the manufacturing flow.

FIG. 3B shows an example of the die 300 after one or more other second stages in manufacturing in accordance with examples as disclosed herein. FIG. 3B also shows a block diagram of a memory system 301 that supports inclusion of one or more dies (e.g., memory die A, memory die B, etc.) similar to the die 300. After the second stage, the die 300 may include a conductive interconnect structure 335 that includes the conductive interconnect 340 and the vias 345.

The conductive interconnect structure 335 may allow for the probe pad 330 to be electrically coupled with the probe pad of another die after the other die is bonded with the die 300. In some examples, the other die may be a logic die whose probe pad is exposed (e.g., physically accessible) after bonding. For instance, the die 300 may be memory die A in the memory system 301 and the probe pad 330 may be electrically coupled with the probe pad of logic die A. In such examples, the die 300 may be stacked on (e.g., bonded with) a second memory die (e.g., memory die B) and the probe pad of the die 300 may be electrically coupled with the probe pad of the second die (e.g., through a similar interconnect structure of the second die).

In some examples, the other die may be a memory die that is configured similarly to the die 300 and whose probe pad is electrically coupled (e.g., through a similar interconnect structure) to the probe pad of a logic die. That is, the other die may be an intermediary die that is electrically and physically between the die 300 and the logic die. For instance, the die 300 may be memory die B in the memory system 301 and the probe pad 330 may be electrically coupled with the probe pad of memory die A (and potentially the probe pad of logic die A).

Although described with reference to a 2:1 memory system configuration where two memory dies are coupled with one logic die, the techniques described herein may be implemented in other memory system configurations, such as a 4:1 configuration, a 4:2 configuration, a 2:2 configuration, a 8:1 configuration, a 12:1 configuration, a 16:1 configuration and so on, where an n:N configuration refers to a configuration with n memory dies and N logic dies. In some examples (e.g., in tightly coupled DRAM (TCDRAM) stacked memory systems) there may be multiple (e.g., 4, 6, 8) n:N configuration stacks (e.g., 8:1 configuration, 12:1 configuration, 16:1 configuration) on a processor (e.g., a CPU, a GPU).

The conductive interconnect structure 335 may be disposed on or coupled with the front side of the die 300, which may be different than other techniques. The front side may refer to the side of the die (or wafer) that is doped during manufacturing to form various components such as transistors and may be the side from which BEOL circuitry is formed. The back side of a die (or wafer) may refer to the side of the die (or wafer) that is opposite of the front side. The conductive interconnect structure 335 may electrically couple the probe pad 330 with A) the TSV 315-a (e.g., through the bond pad 320-a) and B) the die-interface bond pad 350-a. The bond pad 320-a of the TSV 315-a may be partially covered by the SiN material but may have an exposed portion (not covered by the SiN) that is in contact with the conductive interconnect structure 335. In some examples, the BEOL portion 322 may be between (e.g., electrically, physically) the TSV 315-a and the bond pad 320-a of the TSV 315. A die-interface bond pad on one die may be a bond pad (e.g., conductive material) that is configured to bond with a corresponding die-interface bond pad on another die. So, together, the corresponding die-interface bond pads of two dies may form part of an inter-die conductive path between the two dies. A die-interface bond pad may also be referred to as a die-to-die (DD) bond pad or other suitable terminology.

The conductive interconnect structure 335 may include the conductive interconnect 340 and the vias 345 (e.g., via 345-a, via 345-b, via 345-c). The via 345-a may electrically couple, and may be in contact with, the conductive interconnect 340 and the probe pad 330. The probe pad 330 may be partially covered by the SiN material but may have an exposed portion (not covered by the SiN) that is in contact with the via 345-a. The via 345-b may electrically couple, and may be in contact with, the conductive interconnect 340 and the bond pad 320-a of the TSV 315-a. The via 345-c may electrically couple, and may be in contact with, the conductive interconnect 340 and the die-interface bond pad 350-a.

As described in more detail below, forming the conductive interconnect structure 335 may include: depositing a first layer of the oxide material 305, forming the via 345-a, the via 345-b, and the conductive interconnect 340 within the first layer of the oxide material, depositing a second layer of the oxide material 305, and forming the via 345-c and the die-interface bond pad 350-a within the second layer of the oxide material 305. In some examples, one or more of the vias 345, the conductive interconnect 340, or the die-interface bond pad 350-a may be formed using a dual damascene process, where a dual damascene process may refer to a process in which the vias and trenches are patterned in such a way that the metal deposition fills both at the same time. In other examples, one or more of the vias 345, the conductive interconnect 340, or the die-interface bond pad 350-a may be formed using a single damascene or semi-additive process. Dual damascene formations (e.g., RDL, vias) may be detectable with barrier continuity from RDL to via (not shown for simplicity). Further, the RDL/via landing on the probe pads may be detectable relative to other techniques (e.g., techniques in which the hybrid bond pad is floating above the probe pad).

A first layer of the oxide material 305 may be deposited over the probe pad 330.

The via 345-a and the via 345-b may be formed within the first layer of the oxide material 305. For example, an opening for the via 345-a and an opening for the via 345-b may be formed within the oxide material 305 (e.g., within the first layer of the oxide material 305) and conductive material may be deposited therewithin. The via 345-a may be formed such that the via 345-a is electrically coupled with, and potentially in contact with, the probe pad 330. The via 345-b may be formed such that the via 345-b is electrically coupled with, and potentially in contact with, the bond pad 320-a of the TSV 315-a. In some examples, the via 345-a and the via 345-b may be formed using a dual damascene process. In other examples, the via 345-a and the via 345-b may be formed using a single damascene or semi-additive process. In some examples, the via 345-a and the via 345-b may be formed concurrently.

The conductive interconnect 340 may also be formed within the first layer of the oxide material 305. For example, a trench for the conductive interconnect 340 may be formed within the oxide material 305 (e.g., within the first layer of the oxide material 305) and conductive material may be deposited therewithin. The conductive interconnect 340 may be formed such that the conductive interconnect 340 is electrically coupled with, and potentially in contact with, the via 345-a and the via 345-b. Thus, the conductive interconnect 340 may be electrically coupled with the probe pad 330 through the via 345-a and may be electrically coupled with the TSV 315-a through the via 345-b. In some examples, the conductive interconnect 340 may be formed using a dual damascene process. In other examples, conductive interconnect 340 may be formed using a single damascene or semi-additive process. In some examples, the conductive interconnect 340 may be formed concurrently with the via 345-a, the via 345-b, or both.

A second layer of the oxide material 305 may be deposited over the first layer of the oxide material 305, over the conductive interconnect 340, or over both. In some examples, the second layer of the oxide material 305 is deposited after forming the via 345-a, the via 345-b, and the conductive interconnect 340.

The via 345-c may be formed within the second layer of the oxide material 305. For example, an opening for the via 345-c may be formed within the oxide material 305 (e.g., within the second layer of the oxide material 305) and conductive material may be deposited therewithin. The via 345-c may be formed such that the via 345-c is electrically coupled with, and potentially in contact with, the conductive interconnect 340. In some examples, the via 345-c may be formed using a dual damascene process. In other examples, the via 345-c may be formed using a single damascene process. In some examples, the via 345-c may be formed concurrently with the conductive interconnect 340.

The die-interface bond pad 350-a may be formed the within the oxide material 305. For example, a trench for the die-interface bond pad 350-a may be formed within the second layer of the oxide material 305 and conductive material may be deposited therewithin. The die-interface bond pad 350-a may be formed such that the die-interface bond pad 350 is electrically coupled with, and potentially in contact with, the via 345-c. Thus, the conductive interconnect 340 may be electrically coupled with the die-interface bond pad 350-c through the via 345-c. In some examples, the die-interface bond pad 350-a may be formed using a dual damascene process. In some examples, the die-interface bond pad 350-a may be formed concurrently with the via 345-c.

Thus, in some examples, the via 345-a, the via 345-b, and the conductive interconnect 340 may be formed within a first layer of the oxide material 305 that is deposited over the probe pad 330 (and the bond pad 320-a), whereas the via 345-c and the die-interface bond pad 350 may be deposited in a second layer of the oxide material 305 that is deposited over the first layer of the oxide material 305 (and the conductive interconnect 340).

Accordingly, the probe pad 330 may be electrically coupled with the TSV 315-a (e.g., through the via 345-a, the conductive interconnect 340, and the via 345-b) and electrically coupled with the die-interface bond pad 350-a (e.g., through the via 345-a, the conductive interconnect 340, and the via 345-c).

Electrically coupling the probe pad 330 with the TSV 315-a may allow the probe pad 330 to be electrically coupled with the probe pad of another die (e.g., after the bonding process for the two dies) that is coupled with (e.g., below) the die 300. And electrically coupling the probe pad 330 with the die-interface bond pad 350-a may allow the probe pad 330 to be electrically coupled with the probe pad of another die (e.g., after the bonding process for the two dies) that is coupled with (e.g., above) the die 300. For instance, if the die 300 is memory die A in memory system 301, electrically coupling the probe pad 330 with the TSV 315-a may allow the probe pad 330 to be electrically coupled with the probe pad of memory die A, and electrically coupling the probe pad 330 with the die-interface bond pad 350-a may allow the probe pad 330 to be electrically coupled with the probe pad of logic die A.

Electrically coupling the probe pads of stacked dies, as described herein, may allow for post-bonding probing of dies that have probe pads that are inaccessible (e.g., disposed within the dies, not capable of being contacted by a probing device) after bonding.

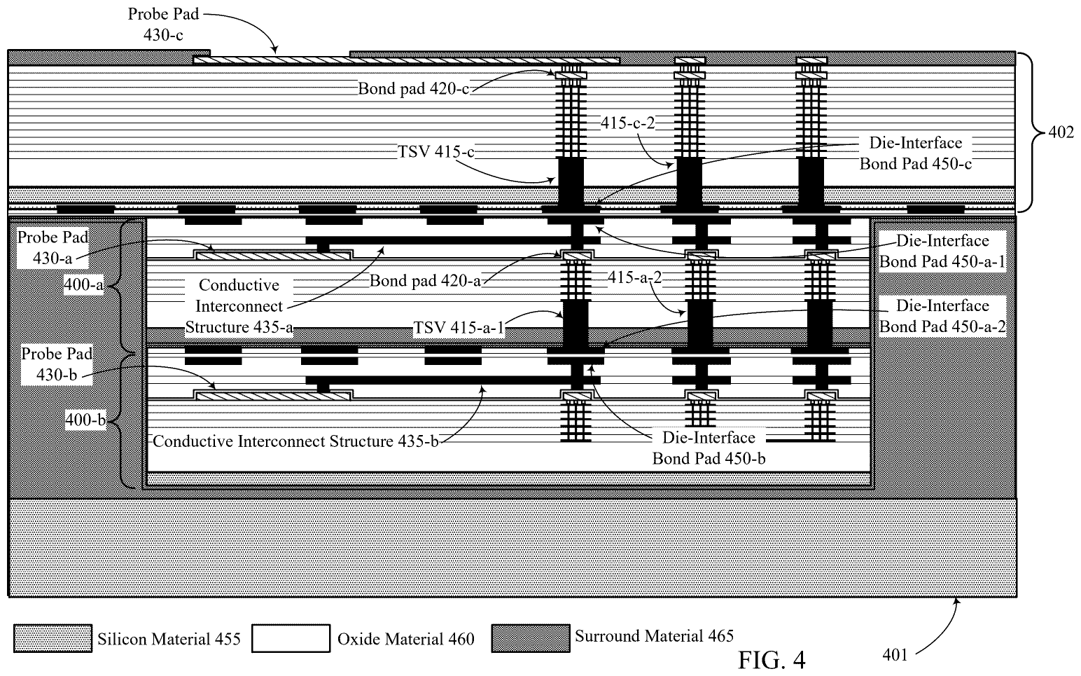

FIG. 4 shows an example of a stacked semiconductor device 401 in accordance with examples as disclosed herein. The stacked semiconductor device 401 may be an example of a stacked memory system with a 2:1 configuration. Thus, the stacked semiconductor device 401 may include logic die 402, memory die 400-a, and memory die 400-b, which may be examples of a die 300 as described with reference to FIGS. 3A and 3B. However, other configurations of the stacked semiconductor device 401 are contemplated and within the scope of the present disclosure. In some examples, the stacked semiconductor device may be an example of the memory system 301 as described with reference to FIG. 3B. The stacked semiconductor device 401 may include various materials including silicon material 455, oxide material 460, and surround material 465.

The stacked semiconductor device 401 may be formed so that one or more conductive paths enable the post-bonding probing of the memory dies 300 through the probe pad 340-a even though the probe pads of the memory dies 300 are internal to the stacked semiconductor device 401 (and thus incapable of being contacted by probing device).

In some examples, each die in the stacked semiconductor device 401 may include a respective probe pad 430. For example, the logic die 402 may include probe pad 430 which may be disposed on the surface of, or partially within, the oxide material of the logic die 402. The probe pad 430-c of the logic die 402 may be external to the logic die 402 (and potentially the stacked semiconductor device 401 and/or the memory system) after bonding so that the probe pad 430-c is exposed (e.g., not covered by another material of the logic die 402) and contactable by a probe device. So, the probe pad 430-c may be on a physically inaccessible surface of the stacked semiconductor device 401. The probe pad 430-c may be electrically coupled with access circuitry for a memory of the logic die 402 and may be configured to convey electrical signals (e.g., associated with probing the memory) to the access circuitry.

The memory die 400-a may include probe pad 430-a which may be disposed on the surface of, or partially within, the oxide material of the memory die 400-a. The probe pad 430-a of the memory die 400-a may be internal (e.g., disposed within) to the memory die 400-a (e.g., in that other materials of the memory die 400-a cover the probe pad 430-a) as well as internal to the stacked semiconductor device 401 (e.g., in that the probe pad 430-a is covered by the logic die 402). So, the probe pad 430-a may be on a physically accessible surface of the stacked semiconductor device 401. The probe pad 430-a may be electrically coupled with access circuitry for a memory of the memory die 400-a and may be configured to convey electrical signals (e.g., associated with probing the memory) to the access circuitry.

The memory die 400-b may include probe pad 430-b which may be disposed on the surface of, or partially within, the oxide material of the memory die 400-b. The probe pad 430-b of the memory die 400-b may be internal (e.g., disposed within) to the memory die 400-b (e.g., in that other materials of the memory die 400-b cover the probe pad 430-a) as well as internal to the stacked semiconductor device 401 (in that the probe pad 430-b is covered by the memory die 400-a and the logic die 402). So, the probe pad 430-b may be on a physically accessible surface of the stacked semiconductor device 401. The probe pad 430-b may be electrically coupled with access circuitry for a memory of the memory die 400-b and may be configured to convey electrical signals (e.g., associated with probing the memory) to the access circuitry.

To enable post-bonding probing of the memory dies 400, even though the probe pads 430 may be internal to the memory dies 400 after bonding, the memory dies 400 may each include a conductive interconnect structure 435 that, together, electrically couple the probe pad 430-c of the logic die 402, the probe pad 430-a-a of memory die 400-a, and the probe pad 430-b-b of the memory die 400-b. For example, the probe pad 430-c of the logic die 402 may be electrically coupled with the probe pad 430-a of the memory die 400-a through the conductive interconnect structure 435-a. Additionally, the probe pad 430-c of the logic die 402 may be electrically coupled with the probe pad 430-b of the memory die 400-b through A) the conductive interconnect structure 435-a and B) the conductive interconnect structure 435-b.

To form the stacked semiconductor device 401, the memory die 400-b may be formed as described with reference to FIGS. 3A and 3B (e.g., so that the memory die 300-b has the conductive interconnect structure 435-b) and the memory die 400-a may be formed as described with reference to FIG. 3A. The memory die 400-b may then be bonded (e.g., via W2W hybrid bonding) with the memory die 400-a. In some examples, the memory die 400-b may be probed before being bonded with the memory die 400-a (e.g., by applying electrical signals directly to the probe pad 430-b, which may be accessible before bonding). In some examples, the memory die 400-a may be probed before being bonded with the memory die 400-b (e.g., by applying electrical signals directly to the probe pad 430-a, which may be accessible before bonding).

Bonding the memory die 400-b with the memory die 400-a may bond the die-interface bond pad 450-b of the memory die 400-b with the die-interface bond pad 450-a-2 of the memory die 400-a so that a conductive path is formed between the conductive interconnect structure 435-b of the memory die 400-b and the TSV 415-a-1 of the memory die 400-a. Bonding the memory die 400-b with the memory die 400-a may, additionally or alternatively, bond other die-interface bond pads 450 of the memory die 400-b with die-interface bond pads 450 of the memory die 400-a.

After the memory die 400-b is bonded with the memory die 400-a, the memory die 400-a may be formed as described with reference to FIG. 3B. For example, the conductive interconnect structure 435-a may be formed within the memory die 400-a.

Bonding the memory die 400-b with the memory die 400-a may corrupt data in one or both of the memory dies 400. So, in some examples, the memory die 400-a may be probed after being bonded with the memory die 400-b (e.g., by applying electrical signals directly to the probe pad 430-a, which may be physically accessible after bonding with the memory die 400-b). Additionally or alternatively, the memory die 400-b may be probed after being bonded with the memory die 400-a. Because the probe pad 430-b may be covered by the memory die 400-a after bonding with the memory die 400-a, the memory die 400-b may be probed through the memory die 400-a (e.g., by applying electrical signals indirectly to the probe pad 430-b through the conductive path between the probe pad 430-a and the probe pad 430-b).

After forming the conductive interconnect structure 435-a as described in FIG. 3B (and potentially after probing one or more of the memory dies 400), the memory die 400-a may be bonded (e.g., via C2W hybrid bonding) with the logic die 402. The logic die 402 may be formed so that the probe pad 430-c is electrically coupled with the TSV 415-c. For example, the probe pad 430-c may be electrically coupled with the TSV 415-c through the bond pad 420-c of the TSV 415-c. Further, the logic die 402 may be formed so that the TSV 415-c is electrically coupled with, and potentially in contact with, the die-interface bond pad 450-c.

Bonding the memory die 400-a with the logic die 402 may bond the die-interface bond pad 450-a-1 of the memory die 400-a with the die-interface bond pad 450-c of the logic die 402 so that a conductive path is formed between the conductive interconnect structure 435-a of the memory die 400-a and the TSV 415-c of the logic die 402. Bonding the memory die 400-a with the logic die 402 may, additionally or alternatively, bond other die-interface bond pads 450 of the memory die 400-a with die-interface bond pads 450 of the logic die 402. Because the probe pad 430-a of the memory die 400-a is electrically coupled with the probe pad 430-b of the memory die 400-b, bonding the memory die 400-a with the logic die 402 may electrically couple the probe pad 430-b of the memory die 400-b with the probe pad 430-c of the logic die 402.

Thus, a conductive path may be formed between the probe pad 430-c of the logic die 402 and the probe pad 430-a of the memory die 400-a, where the conductive path includes, but is not limited to, one or more of: the conductive interconnect structure 435-a, the die-interface bond pad 450-a-1, the die-interface bond pad 450-c, the TSV 415-c, the BEOL portion between the TSV 415 and the bond pad 420-c, and the bond pad 420-c. And a conductive path may be formed between the probe pad 430-c of the logic die 402 and the probe pad 430-b of the memory die 400-b, where the conductive path includes, but is not limited to, one or more of: the conductive interconnect structure 435-b, the die-interface bond pad 450-b, the die-interface bond pad 450-a-2, the TSV 415-a-1, the bond pad 420-a, the die-interface bond pad 450-a-1, the die-interface bond pad 450-c, the TSV 415-c, the BEOL portion between the TSV 415 and the bond pad 420-c, and the bond pad 420-c.

Bonding the memory die 400-a with the logic die 402 may corrupt data in the logic die 402, in the memory die 400-a, in the memory die 400-b, or in any combination thereof. So, in some examples, the memory die 400-a may be probed after being bonded with the logic die 400-b. Because the probe pad 430-a may be covered by the logic die 402 after bonding with the logic die 402, the memory die 400-a may be probed by applying electrical signals to the probe pad 430-c (which may be conveyed to the probe pad 430-a through the conductive path between the probe pad 430-c and the probe pad 430-a). Additionally or alternatively, the memory die 400-b may be probed after the memory die 400-a is bonded with the logic die 402. Because the probe pad 430-b may be covered by the memory die 400-a, the memory die 400-b may be probed by applying electrical signals to the probe pad 430-c (which may be conveyed to the probe pad 430-b through the conductive path between the probe pad 430-c and the probe pad 430-b).

The logic die 402 may be probed (e.g., by applying electrical signals to the probe pad 430-c) before bonding with the memory die 400-a, after bonding with the memory die 400-a, or both. In some examples, bonding the logic die 402 with the memory die 400-a may refer to bonding the logic die 402 with the stack of memory dies (e.g., memory die 400-a and memory die 400-b) that includes the memory die 400-a.

Thus, the conductive interconnect structures 435 may enable post-bonding probing of the memory dies 400 even if the configuration of the stacked semiconductor device 401 prevents a probing device from making contact with the probe pads 430 after one or more die-bonding processes. For example, the conductive interconnect structures 435 may convey electrical signals applied to the probe pad 430-c (which, after bonding, may be located at a physically accessible surface of the stacked semiconductor device 401) to one or both of the probe pad 430-a and the probe pad 430-b (which, after bonding, may be located at physically inaccessible surfaces of the stacked semiconductor device 401).

Although described with both memory dies 400 having a respective conductive interconnect structure 435, in some examples only one of the memory dies 400 may have a conductive interconnect structure (in which case the other memory die 400 may not be capable of being post-bonding probed).

Although shown with the probe pad 430-b of the memory die 400-b being electrically coupled with the probe pad 430-c of the logic die 402 through the conductive interconnect structure 435-a of the memory die 400-a, in some examples the probe pad 430-b may be electrically coupled with the probe pad 430-c, or a different probe pad of the logic die 402, through a different conductive path (e.g., one that omits the conductive interconnect structure 435-a). For instance, the probe pad 430-b may be electrically coupled with the probe pad 430-c or a different probe pad of the logic die 402, through a conductive path that includes the TSV 415-a-2 of memory die 400-a and the TSV 415-c-2 of the logic die 402 (which may be electrically coupled with the probe pad 430-c or another probe pad of the logic die 402). The inclusion of different (e.g., parallel) conductive paths for the probe pads 430 may provide various benefits such as parallel probing and reduced current for probing.

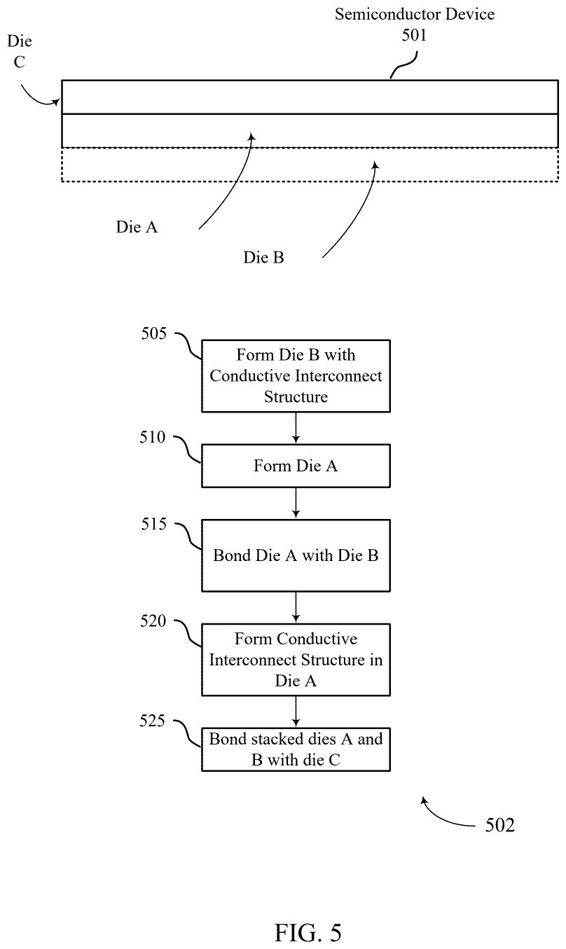

FIG. 5 shows an example of a stacked semiconductor device 501 in accordance with examples as disclosed herein. FIG. 5 also shows an example of a process flow 502 for forming the stacked semiconductor device 501.

In some examples, the stacked semiconductor device 501 may be a stacked memory system with a 2:1 configuration. In such examples, the stacked semiconductor device 501 may include a first memory die (e.g., die A) stacked on a second memory die (e.g., die B), and a logic die (e.g., die C) stacked on the first memory die. The memory dies and logic dies may be examples of corresponding dies described with reference to FIGS. 3A, 3B, and 4. However, other configurations of the stacked semiconductor device 501 are contemplated and within the scope of the present disclosure. The stacked semiconductor device 501 may be an example of the memory system 301 as described with reference to FIG. 3B.

In a first example, the stacked semiconductor device 501 may include: a first die (e.g., die C) comprising a first probe pad (e.g., 430-c) electrically coupled with a first TSB (e.g., TSV 415-c) that extends at least partially through the first die; a second die (e.g., die B) stacked with the first die and comprising a second probe pad (e.g., 430-a) that is positioned within the second die; and a conductive interconnect (e.g., the conductive interconnect of the conductive interconnect structure 435-a) that electrically couples the second probe pad of the second die with the first TSV in the first die, where the second probe pad of the second die is electrically coupled with the first probe pad of the first die through the conductive interconnect and the first TSV.

In some examples, the conductive interconnect is formed from an RDL and is part of a conductive interconnect structure (e.g., conductive interconnect structure 435-a), through which the second probe pad is electrically coupled with the first probe pad, that includes a die-interface bond pad (e.g., die-interface bond pad 450-a-1) of the second die, the die-interface bond pad electrically coupled with, and electrically between, the RDL and the first TSV.

In some examples, the first TSV is coupled with a die-interface bond pad (e.g., die-interface bond pad 450-c), of the first die, which is coupled with a die-interface bond pad (e.g., die-interface bond pad 450-a-1) of the second die. In some examples, the conductive interconnect may be electrically coupled with the first TSV through the die-interface bond pad of the second die and the die-interface bond pad of the first die.

In some examples, the stacked semiconductor device 501 may include a via (e.g., the via 345-c) in contact with the conductive interconnect. In some examples, the conductive interconnect may be electrically coupled with the die-interface bond pad (e.g., the die-interface bond pad 450-a-1) of the second die through the via.

In some examples, the stacked semiconductor device 501 may include a second TSV (e.g., TSV 415-a-1) that extends at least partially through the second die. In some examples, the conductive interconnect may be coupled with the second TSV of the second die. In some examples, the stacked semiconductor device 501 may include a via (e.g., via 345-a) in contact with the conductive interconnect and a bond pad (e.g., bond pad 320-a) of the second TSV. In some examples, the second probe pad may be electrically coupled with the second TSV through the conductive interconnect, the via, and the bond pad of the second TSV.

In some examples, the second die comprises a second TSV (e.g., TSV 415-a-1) and the stacked semiconductor device 501 may include a third die (e.g., die B) comprising a third probe pad (e.g., probe pad 430-b). In some examples, the second probe pad of the second die may be electrically coupled with the third probe pad of the third die through the conductive interconnect and the second TSV. In some examples, the third die is wafer-to-wafer hybrid bonded with the second die, chip-to-chip hybrid bonded with the second die, or chip-to-wafer hybrid bonded with the second die.

In some examples, the stacked semiconductor device 501 may include a third die (e.g., die B) comprising a third probe pad (e.g., probe pad 430-b) that is electrically coupled with the first probe pad of the first die through a conductive path that omits the conductive interconnect. In some examples, the conductive path includes a second conductive interconnect structure of the third die (which may include), a die-interface bond pad of the third die, a TSV (e.g., TSV 415-a-2) of the second die, a die-interface bond pad of the second die, and a TSV (e.g., TSV 415-c-2) of the first die.

In some examples, the stacked semiconductor device 501 may include: a bond pad, of the first TSV, that is electrically coupled with the first probe pad; and a BEOL portion (e.g., BEOL portion 322) electrically coupled with, and electrically between, the first TSV and the bond pad of the first TSV.

In some examples of the stacked semiconductor device 501, the first probe pad is configured to convey electrical signals to access circuitry that is coupled with a memory of the first die and the second probe pad is configured to convey electrical signals to access circuitry that is coupled with a memory of the second die.

In a second example, the stacked semiconductor device 501 may include: a first probe pad (e.g., probe pad 430-c) that is on a physically accessible surface of a stack of semiconductor dies; a second probe pad (e.g., probe pad 430-a, probe pad 430-b) located at a non-physically accessible surface within the stack of semiconductor dies; and a conductive path that electrically couples the first probe pad with the second probe pad.

In some examples, the stack of semiconductor dies may include a first die (e.g., die C) comprising the first probe pad and a second die (e.g., die A, die B) comprising the second probe pad. In some examples, the stack of semiconductor dies may include: a first die-interface bond pad (e.g., die-interface bond pad 450-c) of the first die; a conductive interconnect, formed from a redistribution layer, electrically coupled with the second probe pad through a via; and a second die-interface bond pad (e.g., die-interface bond pad 450-a), of the second die, that electrically couples the conductive interconnect with the first die-interface bond pad.

In some examples, the stacked semiconductor device 501 may include a first via (e.g., via 345-a), of the conductive path, that electrically couples the RDL with the second probe pad; and a second via (e.g., via 345-c), of the conductive path, that electrically couples the RDL with the second die-interface bond pad of the second die.

In some examples of the stacked semiconductor device 501, the stack of semiconductor dies comprises a first die comprising the first probe pad and a second die comprising the second probe pad. In some examples, the stacked semiconductor device 501 may include a conductive interconnect, formed from a redistribution layer, that electrically couples the second probe pad with a first TSV (e.g., TSV 415-c) of the first die and with a second TSV (e.g., TSV 415-a-1) of the second die, where the conductive path comprises the conductive interconnect, the first TSV, and the second TSV.

In some examples, the stacked semiconductor device 501 may include a third probe pad (e.g., probe pad 430-b) located at a second non-physically accessible surface within the stack of semiconductor dies, where a portion of the conductive path electrically couples the third probe pad with the first probe pad.

In a third example, the stacked semiconductor device 501 may include: a logic die (e.g., die C) comprising a probe pad (e.g., probe pad 430-c) electrically coupled with a die-interface bond pad (e.g., die-interface bond pad 450-c) of the logic die; a first memory die (e.g., die B) comprising a first probe pad (e.g., probe pad 430-b) that is electrically coupled, through a first conductive interconnect, with a die-interface bond pad (e.g., die-interface bond pad 450-b) of the first memory die; and a second memory die (e.g., die A), disposed between the first memory die and the logic die, comprising a second probe pad (e.g., probe pad 430-a) that is electrically coupled, through a second conductive interconnect, with the die-interface bond pad of the second memory die and the die-interface bond pad of the logic die.

In some examples, the stacked semiconductor device 501 may include a first die-interface bond pad (e.g., die-interface bond pad 450-a-1), of the second memory die, electrically coupled with, and electrically between, the second conductive interconnect and the die-interface bond pad of the logic die. In some examples, the stacked semiconductor device 501 may include a second die-interface bond pad (e.g., die-interface bond pad 450-a-2), of the second memory die, electrically coupled with, and electrically between, the second conductive interconnect and the die-interface bond pad of the first memory die.

In some examples, the stacked semiconductor device 501 may include a TSV (e.g., TSV 415-a-1), of the second memory die, electrically coupled with the probe pad of the logic die through the die-interface bond pad of the logic die, electrically coupled with the first probe pad of the first memory die through the die-interface bond pad of the second memory die, and electrically coupled with the second probe pad of the second memory die through the second conductive interconnect.

In some examples, the stacked semiconductor device 501 may include a TSV (e.g., TSV 415-c), of the logic die, that is electrically coupled with the probe pad of the logic die, where the probe pad of the logic die is electrically coupled with the die-interface bond pad of the logic die through the TSV.

In some examples, the stacked semiconductor device 501 may include: a TSV (e.g., TSV 415-c) that extends at least partially through the logic die; and a second TSV (e.g., TSV 415-a-1) that extends at least partially through the second memory die, where the second probe pad of the second memory die is electrically coupled, through the second conductive interconnect, with the TSV of the logic die and the second TSV of the second memory die.

In some examples, the stacked semiconductor device 501 may be formed by implementing aspects of the process flow 502.

At 505, the memory die B may be formed with a conductive interconnect structure as described with reference to FIGS. 3A and 3B. At 510, the memory die A may be formed as described with reference to FIG. 3A. At 515, the memory die A may be bonded with the memory die B (e.g., using a W2W hybrid bonding technique). At 520, the conductive interconnect structure may be formed within the memory die A as described with reference to FIG. 3B. At 525, the stack of memory die A and memory die B may be bonded with the logic die A (e.g., using a S2W hybrid bonding technique).

In some examples, the operations at 520 may include: forming a probe pad (e.g., probe pad 330) on surface of a die (e.g., die A) that includes a first TSV (e.g., TSV 315-a) that extends at least partially through the die; forming a first via (e.g., via 345-a), within a layer of an oxide material (e.g., oxide material 305), that is in contact with the probe pad; forming a second via (e.g., via 345-b), within the layer of the oxide material, that is in contact with a bond pad (e.g., bond pad 320-a) of the TSV; and forming a conductive interconnect, within the layer of the oxide material, that is in contact with the first via and the second via and that electrically couples the probe pad with the TSV. In some examples, the first via, the second via, and the conductive interconnect are each formed using a dual damascene process.

In some examples, the operations at 520 may include forming a third via (e.g., via 345-c), within a second layer of the oxide material, that is in contact with the conductive interconnect and a die-interface bond pad (e.g., die-interface bond pad 350-a) of the die.

In some examples, the conductive interconnect is electrically coupled with a die-interface bond pad (e.g., die-interface bond pad 350-a) of the die. In some examples, the operations at 515 or 525 may include bonding the die with a second die (e.g., die B, die C) that includes a second probe pad and a second TSV coupled with a die-interface bond pad of the second die, where bonding the die with the second die bonds the die-interface bond pad of the die with the die-interface bond pad of the second die. In some examples, bonding the die with the second die comprises bonding using a die-to-wafer hybrid bonding technique, a die-to-die hybrid bonding technique, or a wafer-to-wafer hybrid bonding technique.

In some examples, the process flow 502 may include: probing the die, before bonding the die with the second die, by applying electrical signals to the probe pad of the die; and probing the die, after bonding the die with the second die, by applying electrical signals to the second probe pad of the second die.

In some examples, the operations at 515 or 525 may include bonding the die with a second die that includes a second probe pad, where bonding the die with the second die electrically couples the probe pad of the die with the second probe pad of the second die. In some examples, the conductive interconnect is electrically coupled with a die-interface bond pad of the die through the TSV, and where bonding the die with the second die bonds the die-interface bond pad of the die with a die-interface bond pad of the second die.

In some examples, the second probe pad of the second die is electrically coupled with the probe pad of the die through a second conductive interconnect, of the second die, that electrically couples the second probe pad with a die interface bond of the second die. In some examples, the process flow 502 includes forming a third via that is in contact with the conductive interconnect; and forming a die-interface bond pad that is in connect with the third via, where the probe pad is electrically coupled with the die-interface bond pad through the conductive interconnect and the third via.

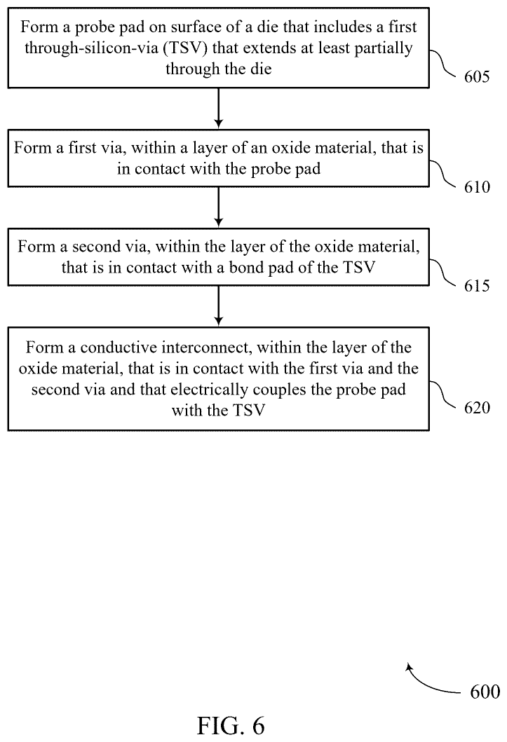

FIG. 6 shows a flowchart illustrating a method 600 that supports die-to-die probe pad connection in a stacked semiconductor device in accordance with examples as disclosed herein. The operations of method 600 may be implemented during manufacture of a stacked semiconductor device.

At 605, the method may include forming a probe pad on surface of a die that includes a first through-silicon-via (TSV) that extends at least partially through the die. At 610, the method may include forming a first via, within a layer of an oxide material, which is in contact with the probe pad. At 615, the method may include forming a second via, within the layer of the oxide material, which is in contact with a bond pad of the TSV. At 620, the method may include forming a conductive interconnect, within the layer of the oxide material, that is in contact with the first via and the second via and that electrically couples the probe pad with the TSV.

In some examples, a stacked semiconductor device may be fabricated using one or more of the following aspects of the present disclosure:
Aspect 1: A method, including forming a probe pad on surface of a die that includes a first through-silicon-via (TSV) that extends at least partially through the die; forming a first via, within a layer of an oxide material, that is in contact with the probe pad; forming a second via, within the layer of the oxide material, that is in contact with a bond pad of the TSV; and forming a conductive interconnect, within the layer of the oxide material, that is in contact with the first via and the second via and that electrically couples the probe pad with the TSV.
Aspect 2: The method of aspect 1, where the first via, the second via, and the conductive interconnect are each formed using a dual damascene process.
Aspect 3: The method of any of aspects 1 through 2, further including forming a third via, within a second layer of the oxide material, that is in contact with the conductive interconnect and a die-interface bond pad of the die.
Aspect 4: The method of aspects 1 through 3, where the conductive interconnect is electrically coupled with a die-interface bond pad of the die and the method, apparatuses, and non-transitory computer-readable medium further includes operations, features, circuitry, logic, means, or instructions, or any combination thereof for bonding the die with a second die that includes a second probe pad and a second TSV coupled with a die-interface bond pad of the second die, where bonding the die with the second die bonds the die-interface bond pad of the die with the die-interface bond pad of the second die.
Aspect 5: The method of aspect 4, where bonding the die with the second die includes bonding using a die-to-wafer hybrid bonding technique, a die-to-die hybrid bonding technique, or a wafer-to-wafer hybrid bonding technique.
Aspect 6: The method of any of aspects 4 through 5, further including probing the die, before bonding the die with the second die, by applying electrical signals to the probe pad of the die and probing the die, after bonding the die with the second die, by applying electrical signals to the second probe pad of the second die.
Aspect 7: The method of aspects 1 through 6, further including bonding the die with a second die that includes a second probe pad, where bonding the die with the second die electrically couples the probe pad of the die with the second probe pad of the second die.
Aspect 8: The method of aspect 7, where the conductive interconnect is electrically coupled with a die-interface bond pad of the die through the TSV and bonding the die with the second die bonds the die-interface bond pad of the die with a die-interface bond pad of the second die.
Aspect 9: The method of aspect 8, where the second probe pad of the second die is electrically coupled with the probe pad of the die through a second conductive interconnect, of the second die, that electrically couples the second probe pad with a die interface bond of the second die.
Aspect 10: The method of any of aspects 8 through 9, further including forming a third via that is in contact with the conductive interconnect and forming a die-interface bond pad that is in connect with the third via, where the probe pad is electrically coupled with the die-interface bond pad through the conductive interconnect and the third via.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 11: An apparatus, including: a first die including a first probe pad electrically coupled with a first through-silicon-via (TSV) that extends at least partially through the first die; a second die stacked with the first die and including a second probe pad that is positioned within the second die; and a conductive interconnect that electrically couples the second probe pad of the second die with the first TSV in the first die, where the second probe pad of the second die is electrically coupled with the first probe pad of the first die through the conductive interconnect and the first TSV.
Aspect 12: The apparatus of aspect 11, where the conductive interconnect is formed from a redistribution layer (RDL) and is part of a conductive interconnect structure, through which the second probe pad is electrically coupled with the first probe pad, that includes a die-interface bond pad of the second die, the die-interface bond pad electrically coupled with, and electrically between, the RDL and the first TSV.
Aspect 13: The apparatus of any of aspects 11 through 12, where the first TSV is coupled with a die-interface bond pad, of the first die, that is coupled with a die-interface bond pad of the second die, and the conductive interconnect is electrically coupled with the first TSV through the die-interface bond pad of the second die and the die-interface bond pad of the first die.
Aspect 14: The apparatus of aspect 13, further including: a via in contact with the conductive interconnect, and where the conductive interconnect is electrically coupled with the die-interface bond pad of the second die through the via.
Aspect 15: The apparatus of any of aspects 11 through 14, further including: a second TSV that extends at least partially through the second die, where the conductive interconnect is coupled with the second TSV of the second die.
Aspect 16: The apparatus of aspect 15, further including: a via in contact with the conductive interconnect and a bond pad of the second TSV, where the second probe pad is electrically coupled with the second TSV through the conductive interconnect, the via, and the bond pad of the second TSV.
Aspect 17: The apparatus of any of aspects 11 through 16, where the second die includes a second TSV, the apparatus further including: a third die including a third probe pad, where the second probe pad of the second die is electrically coupled with the third probe pad of the third die through the conductive interconnect and the second TSV.
Aspect 18: The apparatus of aspect 17, where the third die is wafer-to-wafer hybrid bonded with the second die, die-to-die hybrid bonded with the second die, or die-to-wafer hybrid bonded with the second die.
Aspect 19: The apparatus of any of aspects 11 through 18, further including: a third die including a third probe pad that is electrically coupled with the first probe pad of the first die through a conductive path that omits the conductive interconnect.
Aspect 20: The apparatus of any of aspects 11 through 19, further including: a bond pad, of the first TSV, that is electrically coupled with the first probe pad; and a back-end-of-line (BEOL) portion electrically coupled with, and electrically between, the first TSV and the bond pad of the first TSV.
Aspect 21: The apparatus of any of aspects 11 through 20, where the first probe pad is configured to convey electrical signals to access circuitry that is coupled with a memory of the first die and the second probe pad is configured to convey electrical signals to access circuitry that is coupled with a memory of the second die.

An apparatus is described. The following provides an overview of aspects of the apparatus as described herein:
Aspect 22: A semiconductor device, including: a first probe pad that is on a physically accessible surface of a stack of semiconductor dies; a second probe pad located at a non-physically accessible surface within the stack of semiconductor dies; and a conductive path that electrically couples the first probe pad with the second probe pad.
Aspect 23: The semiconductor device of aspect 22, where the stack of semiconductor dies includes a first die including the first probe pad and a second die including the second probe pad, the semiconductor device further including: a first die-interface bond pad of the first die; a conductive interconnect, formed from a redistribution layer (RDL), electrically coupled with the second probe pad through a via; and a second die-interface bond pad, of the second die, that electrically couples the conductive interconnect with the first die-interface bond pad.
Aspect 24: The semiconductor device of aspect 23, further including: a first via, of the conductive path, that electrically couples the RDL with the second probe pad; and a second via, of the conductive path, that electrically couples the RDL with the second die-interface bond pad of the second die.
Aspect 25: The semiconductor device of any of aspects 22 through 24, where the stack of semiconductor dies includes a first die including the first probe pad and a second die including the second probe pad, the semiconductor device further including: a conductive interconnect, formed from a redistribution layer (RDL), that electrically couples the second probe pad with a first through-silicon-via (TSV) of the first die and with a second TSV of the second die, where the conductive path includes the conductive interconnect, the first TSV, and the second TSV.
Aspect 26: The semiconductor device of any of aspects 22 through 25, further including: a third probe pad located at a second non-physically accessible surface within the stack of semiconductor dies, where a portion of the conductive path electrically couples the third probe pad with the first probe pad.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a first die comprising a first probe pad electrically coupled with a first through-silicon-via (TSV) that extends at least partially through the first die;
a second die stacked with the first die and comprising a second probe pad that is positioned within the second die; and
a conductive interconnect that electrically couples the second probe pad of the second die with the first TSV in the first die, wherein the second probe pad of the second die is electrically coupled with the first probe pad of the first die through the conductive interconnect and the first TSV.

2. The apparatus of claim 1, wherein the conductive interconnect is formed from a redistribution layer (RDL) and is part of a conductive interconnect structure, through which the second probe pad is electrically coupled with the first probe pad, that includes a die-interface bond pad of the second die, the die-interface bond pad electrically coupled with, and electrically between, the RDL and the first TSV.

3. The apparatus of claim 1, wherein:
the first TSV is coupled with a die-interface bond pad, of the first die, that is coupled with a die-interface bond pad of the second die, and
the conductive interconnect is electrically coupled with the first TSV through the die-interface bond pad of the second die and the die-interface bond pad of the first die.

4. The apparatus of claim 3, further comprising:
a via in contact with the conductive interconnect, and wherein the conductive interconnect is electrically coupled with the die-interface bond pad of the second die through the via.

5. The apparatus of claim 1, further comprising:
a second TSV that extends at least partially through the second die, wherein the conductive interconnect is coupled with the second TSV of the second die.

6. The apparatus of claim 5, further comprising:
a via in contact with the conductive interconnect and a bond pad of the second TSV, wherein the second probe pad is electrically coupled with the second TSV through the conductive interconnect, the via, and the bond pad of the second TSV.

7. The apparatus of claim 1, wherein the second die comprises a second TSV, the apparatus further comprising:
a third die comprising a third probe pad, wherein the second probe pad of the second die is electrically coupled with the third probe pad of the third die through the conductive interconnect and the second TSV.

8. The apparatus of claim 7, wherein the third die is wafer-to-wafer hybrid bonded with the second die, die-to-die hybrid bonded with the second die, or die-to-wafer hybrid bonded with the second die.

9. The apparatus of claim 1, further comprising:
a third die comprising a third probe pad that is electrically coupled with the first probe pad of the first die through a conductive path that omits the conductive interconnect.

10. The apparatus of claim 1, further comprising:
a bond pad, of the first TSV, that is electrically coupled with the first probe pad; and
a back-end-of-line (BEOL) portion electrically coupled with, and electrically between, the first TSV and the bond pad of the first TSV.

11. The apparatus of claim 1, wherein the first probe pad is configured to convey electrical signals to access circuitry that is coupled with a memory of the first die and the second probe pad is configured to convey electrical signals to access circuitry that is coupled with a memory of the second die.

12. A method, comprising:
forming a probe pad on surface of a die that includes a first through-silicon-via (TSV) that extends at least partially through the die;
forming a first via, within a layer of an oxide material, that is in contact with the probe pad;
forming a second via, within the layer of the oxide material, that is in contact with a bond pad of the TSV; and
forming a conductive interconnect, within the layer of the oxide material, that is in contact with the first via and the second via and that electrically couples the probe pad with the TSV.

13. The method of claim 12, wherein the first via, the second via, and the conductive interconnect are each formed using a dual damascene process.

14. The method of claim 12, further comprising:
forming a third via, within a second layer of the oxide material, that is in contact with the conductive interconnect and a die-interface bond pad of the die.

15. The method of claim 12, wherein the conductive interconnect is electrically coupled with a die-interface bond pad of the die, the method further comprising:
bonding the die with a second die that includes a second probe pad and a second TSV coupled with a die-interface bond pad of the second die, wherein bonding the die with the second die bonds the die-interface bond pad of the die with the die-interface bond pad of the second die.

16. The method of claim 15, wherein bonding the die with the second die comprises bonding using a die-to-wafer hybrid bonding technique, a die-to-die hybrid bonding technique, or a wafer-to-wafer hybrid bonding technique.

17. The method of claim 15, further comprising:
probing the die, before bonding the die with the second die, by applying electrical signals to the probe pad of the die; and
probing the die, after bonding the die with the second die, by applying electrical signals to the second probe pad of the second die.

18. The method of claim 12, further comprising:
bonding the die with a second die that includes a second probe pad, wherein bonding the die with the second die electrically couples the probe pad of the die with the second probe pad of the second die.

19. The method of claim 18, wherein:
the conductive interconnect is electrically coupled with a die-interface bond pad of the die through the TSV, and
bonding the die with the second die bonds the die-interface bond pad of the die with a die-interface bond pad of the second die.

20. The method of claim 19, wherein the second probe pad of the second die is electrically coupled with the probe pad of the die through a second conductive interconnect, of the second die, that electrically couples the second probe pad with a die interface bond of the second die.

21. The method of claim 19, further comprising:
forming a third via that is in contact with the conductive interconnect; and
forming a die-interface bond pad that is in connect with the third via, wherein the probe pad is electrically coupled with the die-interface bond pad through the conductive interconnect and the third via.

22. A semiconductor device, comprising:
a first probe pad that is on a physically accessible surface of a stack of semiconductor dies;
a second probe pad located at a physically inaccessible surface within the stack of semiconductor dies; and
a conductive path that electrically couples the first probe pad with the second probe pad.

23. The semiconductor device of claim 22, wherein the stack of semiconductor dies comprises a first die comprising the first probe pad and a second die comprising the second probe pad, the semiconductor device further comprising:
a first die-interface bond pad of the first die;
a conductive interconnect, formed from a redistribution layer (RDL), electrically coupled with the second probe pad through a via; and
a second die-interface bond pad, of the second die, that electrically couples the conductive interconnect with the first die-interface bond pad.

24. The semiconductor device of claim 23, further comprising:
a first via, of the conductive path, that electrically couples the RDL with the second probe pad; and
a second via, of the conductive path, that electrically couples the RDL with the second die-interface bond pad of the second die.

25. The semiconductor device of claim 22, wherein the stack of semiconductor dies comprises a first die comprising the first probe pad and a second die comprising the second probe pad, the semiconductor device further comprising:
a conductive interconnect, formed from a redistribution layer (RDL), that electrically couples the second probe pad with a first through-silicon-via (TSV) of the first die and with a second TSV of the second die, wherein the conductive path comprises the conductive interconnect, the first TSV, and the second TSV.

26. The semiconductor device of claim 22, further comprising:
a third probe pad located at a second physically inaccessible surface within the stack of semiconductor dies, wherein a portion of the conductive path electrically couples the third probe pad with the first probe pad.
